(19) United States
(12) Patent Application Publication
(10) Pub. No.: US 2004/0066618 A1
(43) Pub. Date: Apr. 8, 2004

(54) Shock-resistant enclosure

(76) Inventors: Michael R. Layton, Clayton, CA (US); John C. Holloway, Pleasanton, CA (US); Mark A. Collins, Antioch, CA (US); Patrick J. Phipps, Antioch, CA (US)

Correspondence Address: DORSEY & WHITNEY LLP, Suite 3400, Four Embarcadero Center, San Francisco, CA, 94111-4187, US

(21) Appl. No.: 10/633,368

(22) Filed: Jul. 31, 2003

Related U.S. Application Data
(60) Provisional application No. 60/400,940, filed on Aug. 1, 2002.

(51) Int. Cl. H05K 5/00

(52) U.S. Cl. 361/683

(57) ABSTRACT

Shock-resistant enclosure having a housing to which a fragile element is rigidly mounted, and a plurality of discrete shock absorbing elements projecting from the housing in different directions for receiving impacts which would otherwise strike the housing. In some embodiments, the shock absorbing elements include elastomeric bumpers which are formed integrally with a gasket that provides a seal between two sections of the housing. In others, they include plastic fenders or springs which are formed integrally with and of the same material as the housing.

### RELATED APPLICATION

Provisional Application No. 60/400,940, filed Aug. 1, 2002, the priority of which is claimed.

### BACKGROUND OF THE INVENTION

1. Field of Invention

This invention pertains generally to enclosures for devices with fragile components and, more particularly, to a shock-resistant enclosure which is particularly suitable for use with solid state angular rate sensors and the like.

2. Related Art

Angular rate sensors commonly have sensing elements in the form of small quartz tuning forks which are relatively fragile and require protection from impact prior to, during and after installation. Heretofore, such protection has been provided by mounting the sensing element on a support structure such as a printed circuit board and then suspending the support structure within a housing with an elastomer or other flexible material. The flexible suspension absorbs a portion of applied shocks and limits the energy transmitted to the sensing element.

While providing some measure of shock protection, the flexible material can also degrade the performance of the sensor. This happens because the flexible material permits movement of the sensing element within the enclosure in response to shock or vibration of the unit. If sensing element rotates within the housing, it will produce an erroneous output signal which cannot be distinguished from the signals produced by rotation of the unit and the structure on which it is mounted.

### OBJECTS AND SUMMARY OF THE INVENTION

It is, in general, an object of the invention to provide a new and improved shock-resistant enclosure.

Another object of the invention is to provide a shock resistant enclosure of the above character which is particularly suitable for use in angular rate sensors.

These and other objects are achieved in accordance with the invention by providing a shock-resistant enclosure which has a housing to which a fragile element is rigidly mounted, and a plurality of discrete shock absorbing elements projecting from the housing in different directions for receiving impacts which would otherwise strike the housing. In some embodiments, the shock absorbing elements include elastomeric bumpers which are formed integrally with a gasket that provides a seal between two sections of the housing. In others, they include plastic fenders or springs which are formed integrally with and of the same material as the housing.

### BRIEF DESCRIPTION OF THE DRAWINGS

FIG. 1 is an isometric view of one embodiment of a shock-resistant enclosure in accordance with the invention.

FIG. 2 is an isometric view of a combined gasket and bumper structure utilized in the embodiment of FIG. 1.

FIG. 3 is an enlarged, fragmentary, isometric view illustrating the manner in which forces impact upon the shock absorbing elements in the embodiment of FIG. 1.

FIGS. 4-6 are graphical representations illustrating the manner in which shock impulses are mitigated by the invention.

FIGS. 7 and 8 are isometric views of additional embodiments of a shock-resistant enclosure in accordance with the invention.

### DETAILED DESCRIPTION

As illustrated in FIG. 1, the shock-resistant enclosure includes a housing 11 in which a device such as an angular rate sensor having a fragile element such as a quartz tuning fork is enclosed. The fragile element is affixed rigidly to the housing, with no shock absorbing element between the fragile element and the housing. It could, for example, be mounted on a circuit board affixed to the housing, or it could be affixed with an adhesive. As used herein, the term “rigidly” does not require absolute rigidity, but rather encompasses any type of mount that does not include a shock absorber.

The housing is formed in two sections—a base 12 and a cover 13 which, in the embodiment illustrated, are held together by screws 14. It will be understood, however, that the two sections can be held together by any suitable means, including rivets, snaps or with an adhesive.

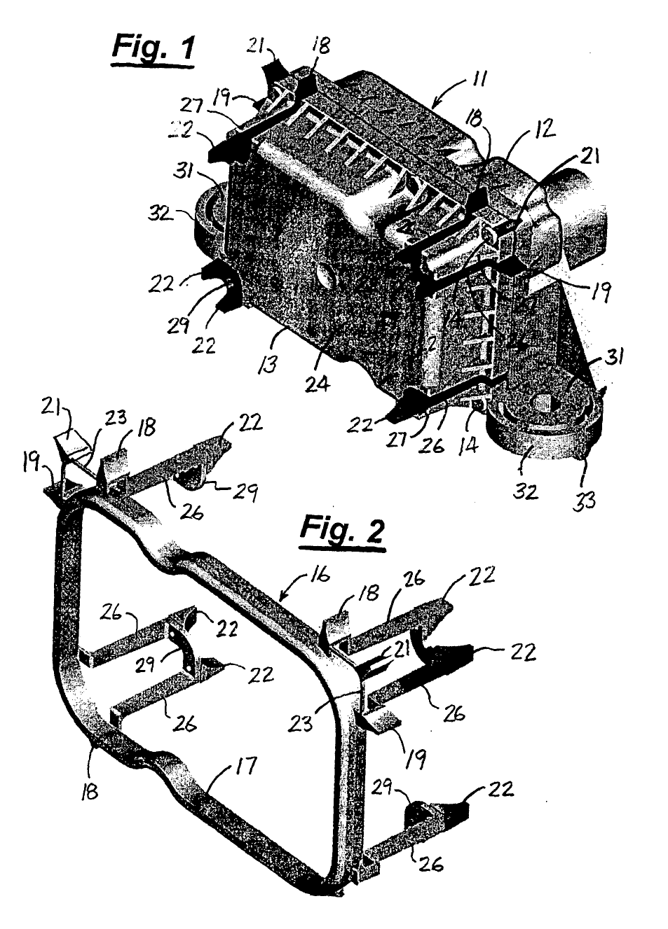

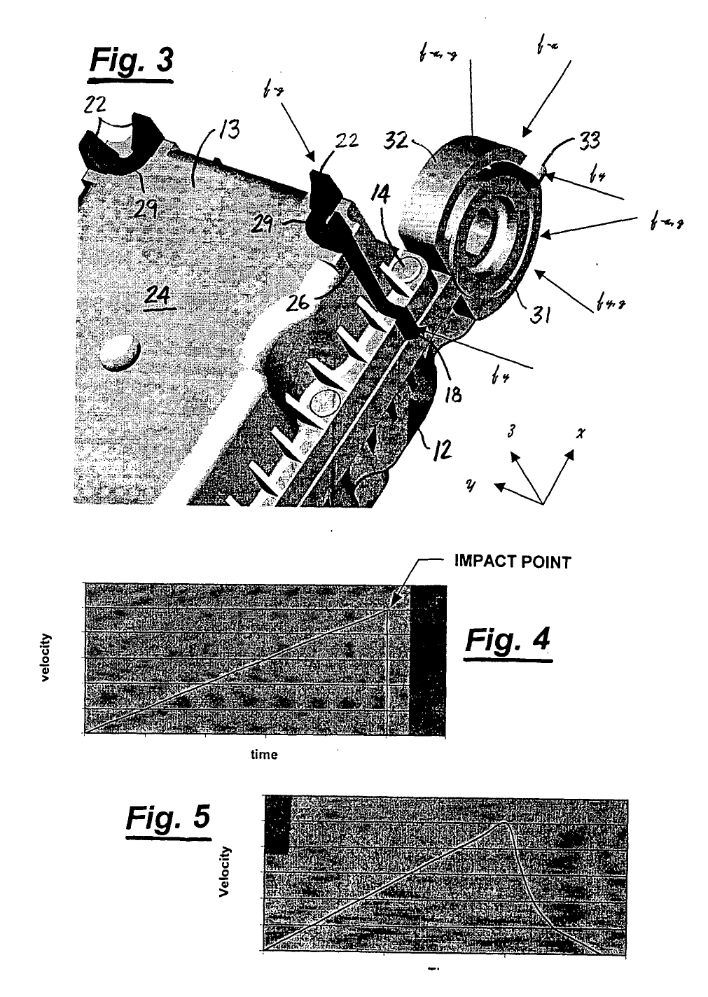

An elastomeric gasket and bumper structure 16 provides both a seal between the two sections and protection from impact or shock. As best seen in FIG. 2, structure 16 includes a generally rectangular sealing ring 17 which is received between the two sections of the housing, and a plurality of discrete bumpers 18, 19, 21, 22 which project from the housing in different directions and serve as shock absorbing elements.

Bumpers 18, 19 lie generally in the plane of the sealing ring and project laterally from sides and ends of the housing. Bumpers 21 also lie generally in the plane of the seal and extend diagonally from the corners of the housing. They are connected to the base portions of bumpers 18, 19 by runners or bridges 23. Bumpers 22 project from a face 24 of the housing which is generally parallel to the plane of sealing ring 17. They are joined to bumpers 18, 19 and the sealing ring by runners 26.

The gasket and bumpers are formed as an integral structure of rubber or another suitable elastomer by a process such as injection molding.

The bumpers are positioned near the corners of the housing and, in the embodiment illustrated, are held in place by cornerpieces 27 which are retained by the screws 14 that hold the two sections of the housing together. Runners 23 are thus captured between the bottoms of the cornerpieces and a flange on the housing cover, and runners 26 are embedded in recesses formed in the side walls of the cover next to the cornerpieces. The two bumpers at each corner are joined together by gussets 29 that are received in recesses in the outer face of the cover.

Alternatively, if desired, the bumpers and runners can be over-molded onto the housing to form an integral structure, with the runners being received or embedded in recesses in the outer surfaces of the housing walls and thereby integrally attached to the housing. In that case, the cornerpieces are not required.

The bumpers are tapered and decrease in cross section away from the housing, i.e., broader at the base and thinner at the tip. This gradient in flexibility has been found to provide better shock absorption characteristics than bumpers having a uniform cross section throughout their length.

Mounting pads 31 extend laterally from the base of the housing, and additional impact resistance is provided by shock absorbing fenders 32 which surround the outer edge portions of the pads. In the embodiment illustrated, the fenders are in the form of C-shaped springs which are generally coplanar with and spaced laterally from the mounting pads. Fenders 32 include lugs 33 which project beyond the lower surfaces of the mounting pads. The fenders and lugs are formed integrally with and of the same material the base section of the housing, and in the presently preferred embodiments, they are formed of a plastic material.

The bumpers and fenders protect the housing and its contents from impacts such as being dropped onto the floor or other hard surface either prior to or during installation, as well as impacts or shock occurring thereafter. With the bumpers and fenders extending in different directions, an impact coming from any direction can be absorbed by one or more of them, rather than striking the housing directly.

Thus, bumpers 18, 19, 21 will absorb impacts in the plane of the sealing ring, i.e., those directed toward the sides and/or ends of the housing, and bumpers 22 will absorb impacts directed toward the face of the cover. Fenders 32 absorb impacts both in and perpendicular to the plane of the mounting pads.

The shock energy transmitted to the tuning fork or other fragile element within the housing is a result of the acceleration that occurs when the device receives an impact. Acceleration is the change in velocity over time, or dv/dt, and for a given change in velocity, the amount of acceleration can be decreased by extending the time over which it occurs.

FIG. 4 shows the effect of a body impacting upon a hard, immovable surface. That causes an abrupt change in velocity in a very short time and, thus, a very large shock. This impulse is sometimes referred to as a “saw-tooth” shock pulse.

The invention reduces the shock by extending the time of acceleration. In the example of FIG. 5, the elastomeric bumpers and plastic fenders absorb the shock pulse to the point of zero velocity. While this total absorption is the optimal condition, it is usually not necessary to provide this much mitigation.

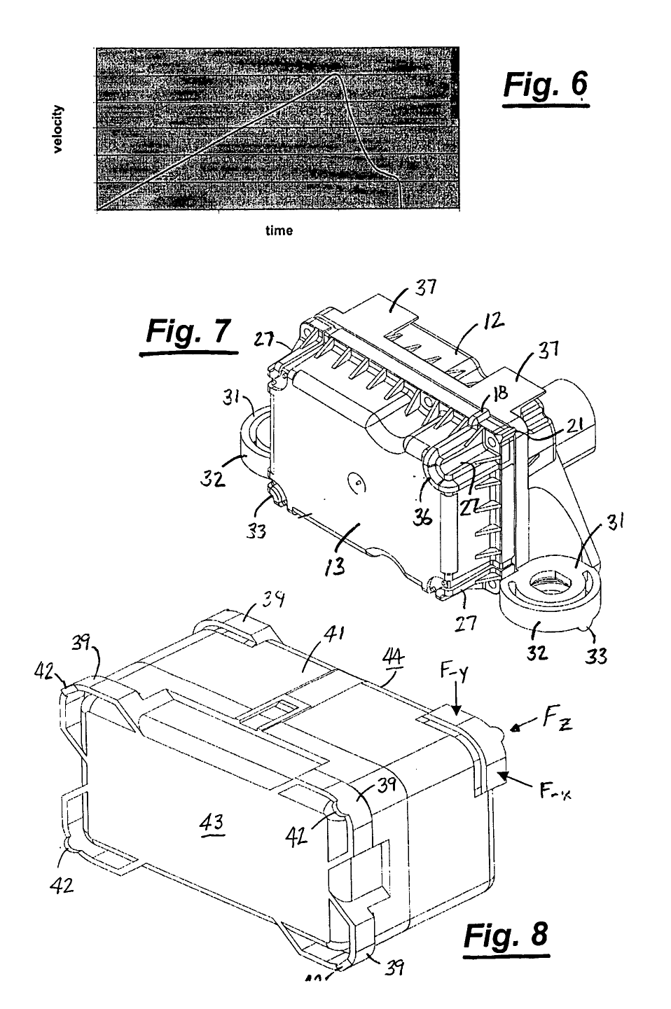

FIG. 6 illustrates a practical example in which the majority of the energy is absorbed. Here, the velocity decreases gradually until the shock absorbers bottom out or otherwise reach the limit of their capacity, following which the remaining energy is dissipated in a very short period of time. Since the velocity is reduced substantially before the limit is reached, acceleration and shock are reduced significantly.

The embodiment of FIG. 7 is similar to that of FIG. 1 except for the bumpers. In this embodiment, bumpers 18, 21 once again extend in the plane of the seal, but bumpers 22 have been replaced with rounded bumpers 36 which project beyond the outer face of cover 13. In addition, the upper side of the housing is protected by leaf springs 37. Those springs are formed integrally with and of the same material as base 12, and they are cantilevered from it.

In the embodiment of FIG. 8, shock absorbing fenders 39 are provided at the corners of the housing 41. These fenders extend around the corners and are spaced laterally from them, with lugs 42 projecting beyond the surfaces 43, 44 of the housing which are bounded by the corners. They absorb impacts in the planes of the fenders as well as those which are perpendicular or oblique to those planes. Fenders 39 and lugs 42 are formed integrally with and of the same material (e.g. plastic) as the housing.

The invention has a number of important features and advantages. It provides effective protection against impact and shock for fragile elements within a housing while permitting those elements to be mounted rigidly to the housing.

In applications where the enclosure is for a rate sensor or other device in which the fragile element is mounted on a circuit board and connections with the circuit board are made through the housing via pins, the need for flexible connections between the circuit board and the pins is eliminated. With the circuit board affixed rigidly to the housing, the connections can also be rigid.

With the individual bumpers, the elastomeric material is employed only in discrete locations and is configured to provide more desirable shock absorbing characteristics.

In some embodiments, the elastomeric bumpers are formed as part of an integral structure which also includes a sealing gasket for the housing, and both the bumpers and the gasket are formed in a single manufacturing step. Being connected, they can be molded simultaneously, which provides a significant advantage both in manufacturing and in handling.

Additional shock absorbing elements are molded into the housing itself and designed to absorb impact along more than one axis without interfering with the mounting of the device in its ultimate application, e.g. a yaw rate sensor bolted into an automobile or other vehicle.

The bumpers and gasket are provided economically by forming them of the same material and in a single manufacturing process. Further cost saving results from having individual bumpers in discrete locations, rather than a single coating of elastomeric material over the entire housing, and the tapered shape of the shock absorbers provides a substantially smaller peak rate of acceleration than a constant cross section. If desired, the rubber bumpers and gasket can be molded onto the housing or attached by other suitable means.

The fenders are also produced economically by forming them integrally with the housing without the use of a separate material or an over-molding step. Their shape and positions allow them to absorb shock from a number of different angles, and they are designed to deflect during installation so as not to interfere with the mounting of the housing.

It is apparent from the foregoing that a new and improved shock-resistant enclosure has been provided. While only certain presently preferred embodiments have been described in detail, as will be apparent to those familiar with the art, certain changes and modifications can be made without departing from the scope of the invention as defined by the following claims.

1. A shock-resistant enclosure, comprising a housing to which a fragile element is rigidly mounted, and a plurality of discrete shock absorbing elements projecting in different directions from the housing for receiving impacts which would otherwise strike the housing.

2. The shock-resistant enclosure of claim 1 wherein the shock absorbing elements are fabricated of an elastomeric material affixed to the housing.

3. The shock-resistant enclosure of claim 1 wherein the shock absorbing elements are formed integrally with the housing and of the same material as the housing.

4. The shock-resistant enclosure of claim 1 wherein the shock absorbing elements include springs.

5. The shock-resistant enclosure of claim 1 wherein the shock absorbing elements are tapered and decrease in cross-sectional area away from the housing.

6. The shock-resistant enclosure of claim 1 wherein the shock absorbing elements are formed integrally with a gasket which seals two sections of the housing together.

7. The shock-resistant enclosure of claim 1 wherein at least some of the shock absorbing elements extend beyond a mounting surface of the housing and are adapted to deflect so as not to prevent the mounting surface from making direct contact with a surface on which the enclosure is installed.

8. The shock-resistant enclosure of claim 1 further including a mounting pad which projects from the housing, and a shock absorbing fender spaced laterally from the mounting pad.

9. The shock-resistant enclosure of claim 8 wherein the mounting pad and the fender are formed integrally with the housing.

10. A shock-resistant enclosure, comprising a housing having base and cover sections, and a combined sealing gasket and shock absorbing structure formed integrally of an elastomeric material with a sealing portion disposed between the base and cover sections of the housing and a plurality of discrete shock absorbing elements extending from the sealing portion and projecting from different sides of the housing.

11. The shock-resistant enclosure of claim 10 wherein the shock absorbing elements are connected to the sealing portion by runners which are embedded in the walls of the housing.

12. The shock-resistant enclosure of claim 11 wherein the runners are embedded in recesses near the corners of the housing and held in place by cornerpieces retained by fasteners that also hold the two sections of the housing together.

13. The shock-resistant enclosure of claim 11 wherein the shock absorbing elements and runners are over-molded onto the housing, with the runners being embedded in recesses near the corners of the housing and thereby integrally attached to the housing.

14. The shock-resistant enclosure of claim 10 wherein the shock absorbing elements are tapered and decrease in cross-sectional area away from the housing.

15. The shock-resistant enclosure of claim 10 including shock absorbing leaf springs which extend in a direction generally parallel to one side of the housing.

16. The shock-resistant enclosure of claim 15 wherein the leaf springs are formed integrally with one of the sections of the housing and extend from that section in cantilevered fashion.

17. The shock-resistant enclosure of claim 10 further including a mounting pad which projects from the housing, and a shock absorbing fender spaced laterally from the mounting pad.

18. The shock-resistant enclosure of claim 17 wherein the mounting pad and the fender are formed integrally with the housing.

19. A shock-resistant enclosure, comprising a housing to which a fragile element is rigidly mounted, a mounting pad which projects from the housing, and a shock absorbing fender spaced laterally from the mounting pad for receiving impacts which would otherwise strike the mounting pad.

20. The shock-resistant enclosure of claim 19 wherein the mounting pad and the fender are formed integrally with the housing.

21. The shock-absorbing enclosure of claim 19 wherein the fender includes a lug which extends beyond a surface of the mounting pad for receiving impacts which might otherwise strike the surface of the pad.

22. The shock-resistant enclosure of claim 21 wherein the housing, the mounting pad, and the fender are fabricated of a plastic material.

23. The shock-resistant enclosure of claim 19 wherein the mounting pad is generally circular, and the fender is generally C-shaped.

24. A shock-resistant enclosure, comprising a housing to which a fragile element is rigidly mounted, and a plurality of leaf springs formed integrally with and extending from the housing for receiving impacts that would otherwise strike the housing.

25. The shock-resistant enclosure of claim 24 wherein the leaf springs overlie one side of the housing.

26. A shock-resistant enclosure, comprising a housing to which a fragile element is rigidly mounted, and a plurality of shock absorbing fenders which extend around and are spaced from corner portions of the housing for receiving impacts that would otherwise strike the housing.

27. The shock-resistant enclosure of claim 26 wherein the fenders are formed integrally with the housing.

28. The shock-resistant enclosure of claim 27 wherein the housing and the fenders are fabricated of a plastic material.

29. The shock-resistant enclosure of claim 26 wherein the fenders include lugs which extend beyond a side of the housing bounded by the corner portions.
